(19) United States
(12) Patent Application Publication
(10) Pub. No.: US 2015/0092373 A1
(43) Pub. Date: Apr. 2, 2015

(54) MOUNTING SOLUTION FOR COMPONENTS ON A VERY FINE PITCH ARRAY

(71) Applicant: ALCATEL-LUCENT CANADA INC., Ottawa (CA)

(72) Inventors: Alex CHAN, Nepean (CA); Paul J. BROWN, Wakefield (CA)

(73) Assignee: ALCATEL-LUCENT CANADA INC., Ottawa (CA)

(21) Appl. No.: 14/043,970

(22) Filed: Oct. 2, 2013

(51) Int. Cl. H05K 1/11; H05K 13/04; G06F 17/50

(52) U.S. Cl. CPC H05K 1/111; G06F 17/5077; H05K 13/0465; H05K 2201/09381; H05K 2201/10893
USPC 361/767; 716/137; 29/840

(57) ABSTRACT

Various exemplary embodiments relate to a printed circuit board (PCB) comprising a ball grid array (BGA) of BGA pads on one side of the PCB, arranged in a grid pattern; through-hole vias, including a via pad, arranged in said grid pattern electrically connected to said BGA pads; a solder mask covering the via pad with an opening; a solder pad within said opening electrically connected to said via pad; and a two-lead component attached to said solder pad.

### TECHNICAL FIELD

Various exemplary embodiments disclosed herein relate generally to surface mount components on a circuit board.

### BACKGROUND

Surface mount components are prevalent in many devices today. They allow components to be attached in compact spaces. A ball grid array allows a device to be directly attached to another circuit board without socket mounting, which leads to better performance at high speeds. In order to make smaller devices the spacing of the ball grid array has decreased over time. As technology develops, a way to attach components on increasingly compact grids is necessary.

### SUMMARY

A brief summary of various exemplary embodiments is presented below. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

Various exemplary embodiments relate to a printed circuit board (PCB) comprising a ball grid array (BGA) of BGA pads on one side of the PCB, arranged in a grid pattern; through-hole vias, including a via pad, arranged in said grid pattern electrically connected to said BGA pads; a solder mask covering the via pad with an opening; a solder pad within said opening electrically connected to said via pad; and a two-lead component attached to said solder pad.

Various embodiments describe the PCB, wherein the grid pattern is square.

Various embodiments describe the PCB, wherein the grid pattern has 0.65 mm pitch.

Various embodiments describe the PCB, wherein said solder pad is substantially rectangular.

Various embodiments describe the PCB, wherein the two-lead component is an Imperial 0201 component.

Various embodiments describe the PCB, wherein the Imperial 0201 component is a discrete component.

Various embodiments describe the PCB, wherein the areas are substantially rectangular and each edge makes contact with the corresponding via pad.

Various exemplary embodiments relate to a method of manufacturing a PCB comprising the steps of selecting two adjacent through-hole vias on a printed circuit board (PCB), wherein the PCB has a ball grid array (BGA) of BGA pads on one side of the PCB arranged in a grid pattern; covering each via with a respective solder mask; removing areas from said solder masks, wherein the areas overlap the holes of the respective through-hole vias; placing solder pads in said areas; and attaching a two-lead component to said two adjacent through-hole vias using said solder pads.

Various exemplary embodiments relate to A computer aided design tool implemented on a computing device for accommodating a two-lead component on in a 0.65 mm by 0.65 mm pitch ball grid array (BGA) printed circuit board (PCB) comprising a design tool mode configured to select two adjacent through-hole vias on the printed circuit board (PCB) for connection to a two-lead component a design tool mode configured to identify a placement of solder pads and shape of solder pads on the two adjacent through-hole vias, wherein the placement allows a two-lead component to connect to two adjacent through-hole vias, and wherein the solder pads overlap the holes of the respective through-hole vias.

### BRIEF DESCRIPTION OF THE DRAWINGS

In order to better understand various exemplary embodiments, reference is made to the accompanying drawings, wherein:

FIG. 1 illustrates an embodiment of a surface mount component on a very fine pitch array;

FIG. 2 illustrates an embodiment of a process for attaching a surface mount component on a very fine pitch array; and

FIG. 3 illustrates a cross sectional view of the surface mount component on a very fine pitch array.

To facilitate understanding, identical reference numerals have been used to designate elements having substantially the same or similar structure and/or substantially the same or similar function.

### DETAILED DESCRIPTION

The description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments may be combined with one or more other embodiments to form new embodiments.

Referring now to the drawings, in which like numerals refer to like components or steps, there are disclosed broad aspects of various exemplary embodiments.

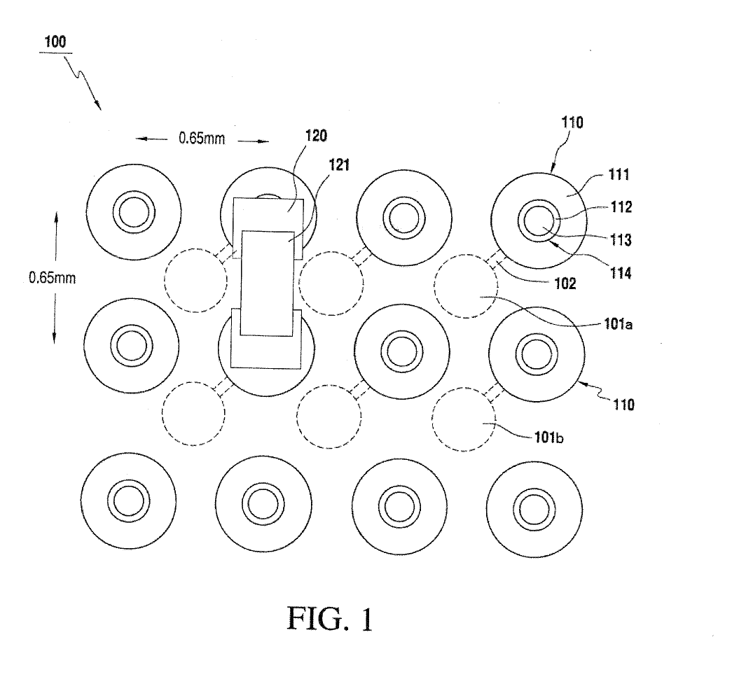

FIG. 1 illustrates an embodiment of a surface mount component on a very fine pitch array. This includes a portion of a circuit board 100, which contains a ball grid array (BGA) of BGA pads 101 on one side. Two BGA pads 101 are labeled (101a and 101b), but others are present in the grid pattern as illustrated in FIG. 1. In an exemplary embodiment BGA pads 101 form a 0.65 mm pitch grid, meaning that BGA pads 101a and 101b are spaced 0.65 mm center-to-center apart in a square grid. However, BGA pads 101 may also form a substantially rectangular grid, where the BGA pads 101 are spaced 0.65 mm apart or another spacing. The grid may also be varied in its arrangement. BGA pad 101 is connected to corresponding via 110 by way of trace 102.

The standard structure of via 110 includes via pad 111 and through-hole via 114, having via barrel 112 and epoxy fill 113. Typically, via pad 111 will be substantially circular in shape and have a diameter of 0.46 mm, through-hole via 112 will be substantially circular in shape and have a radius of 0.25 mm, and epoxy fill 113 will be substantially circular in shape and have a radius of 0.2 mm. All dimensions may have a tolerance of ±10%. Via barrel 112 has an outer radius to fit in through-hole via 114 and contain epoxy fill 113.

On the side of circuit board 100 opposite BGA pad 101, component 121 is mounted to two adjacent through-hole vias using solder pad 120 on each via. Vias 110 also form a 0.65 mm pitch center-to-center grid, which is offset from the BGA pad grid, such that they do not overlap.

In an exemplary embodiment, component 121 is a two-lead 0201 component, having a length of 0.5 mm and a width of 0.25 mm. In the embodiment component 121 is a discrete component. In some cases, the component 121 is a capacitor that can be used for decoupling. Solder pad 120 is used to extend the conductive area of via pad 111 to connect component 121 between two BGA pads due to the dimensions of via 110 on a 0.65 pitch BGA.

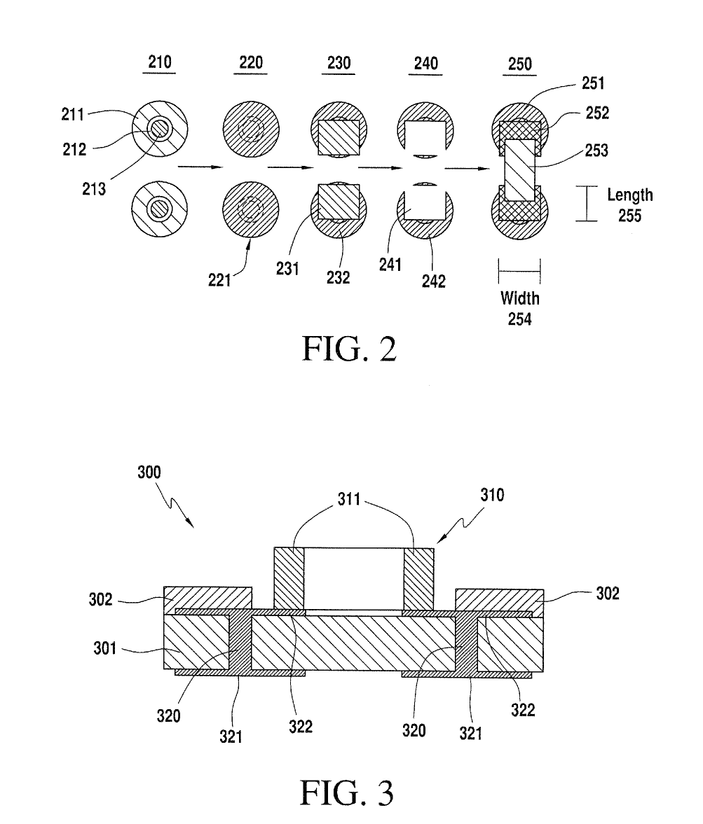

FIG. 2 illustrates an embodiment of a process for attaching a surface mount component on a very fine pitch array. The method generally consists of steps 210, 220, 230, 240, and 250. The final product results in the structure depicted in FIG. 3.

At step 210, two adjacent vias are selected. The structure of each via includes via pad 211 and through-hole via 212, which initially has epoxy fill 213. Typically, a hole is drilled and then coated with a conductive material, such as copper. Other via construction methods are recognized by those skilled in the art.

At step 220, two adjacent vias are entirely covered with solder mask 221. In an exemplary embodiment, solder mask 221 is a thin layer of a nonconductive polymer. Solder mask 221 prevents the copper portions of the via from oxidizing and prevents unintended solder bridges from accidentally forming on the circuit board. Solder mask may be applied using a silkscreen process.

At step 230, identified landing area 231 is identified in relation to the via and solder mask 242. Identified landing area 231 is placed such that component 253 may be conductively attached to two adjacent vias. Typically, this will require identified landing area 231 to extend beyond solder mask 232. However, in an exemplary embodiment, solder mask 232 will touch each side of identified landing area 231, as depicted in FIG. 2.

At step 240, a portion of solder mask 232 corresponding to identified landing area 231 is removed to form landing area 241. This may be accomplished by etching the solder mask to remove material. In an exemplary embodiment solder mask 232 is modified using photolithography. However, other processes may be used to remove a portion of solder mask 232.

At step 250, component 253 is attached using solder pad 252 to two adjacent vias, which are partially covered by solder mask 251. Solder pad 252 has length 255 and width 254 to substantially fit within landing area 241. In an exemplary embodiment, solder pad 252 is substantially rectangular in shape. However, solder pad 252 may have other shapes such that an electrical connection can be made with component 253.

The steps 210, 220, 230, 240, and 250 may be carried out by a computer controlled machine. In an exemplary embodiment, a computer aided design tool allows the selection of vias and arrangement of the solder mask, solder pad, and component to be substantially automated. The computer aided design tool may automatically identify appropriate spacing and shape of the solder pad to place standard components on a BGA. A computer aided design tool may also provide instructions to control a machine to manufacture the modified circuit board. Instructions may be exported to the machine or the design tool may directly control the machine.

FIG. 3 illustrates a cross sectional view of finished assembly 300 of a surface mount component on a very fine pitch array. This view applies to both the device formed at step 250 of FIG. 2 and attached component 121 of FIG. 1.

Printed Circuit Board (PCB) 301 has vias with filled via barrels 320 attached to backside via 321 on the back side of PCB 301 and extended landing areas 322 that are formed on the front side of PCB 301. Extended landing areas 322 are formed by the original via structure and the added solder pad which is used to attach component 310 to PCB 301. Extended landing areas 322 protrude away from filled via barrels 320 such that ports 311 of component 310 may be conductively attached to backside vias 321 through filled via barrels 320. In an exemplary embodiment extended landing area 322 extends such that it ends to the inner side of ports 311. Extended landing area 322 is partially covered by solder mask 302 such that conductive portions are not unnecessarily exposed.

While the figures and descriptions may depict regular circular or rectangular shapes of different elements in exemplary embodiments, it should be understood that alternative shapes may be used such as imperfect polygons and rounded forms. These alternative shapes may be substantially similar to the depicted shapes in area and outline.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be effected while remaining within the spirit and scope of the invention. Accordingly, the foregoing disclosure, description, and figures are for illustrative purposes only and do not in any way limit the invention, which is defined only by the claims.

What is claimed is:

1. A printed circuit board (PCB) comprising:
a ball grid array (BGA) of BGA pads on one side of the PCB, arranged in a grid pattern;
through-hole vias, including a via pad, arranged in said grid pattern electrically connected to said BGA pads;
a solder mask covering the via pad with an opening;
a solder pad within said opening electrically connected to said via pad; and
a two-lead component attached to said solder pad.

2. The PCB of claim 1, wherein the grid pattern is square.

3. The PCB of claim 2, wherein the grid pattern has 0.65 mm pitch.

4. The PCB of claim 1, wherein the grid pattern is substantially rectangular.

5. The PCB of claim 1, wherein said solder pad is substantially rectangular.

6. The PCB of claim 1, wherein the two-lead component is an Imperial 0201 component.

7. The PCB of claim 6, wherein the Imperial 0201 component is a discrete component.

8. The PCB of claim 1, wherein the opening is substantially rectangular and has contact with the via pad on all four perimeter edges.

9. A method of manufacturing a PCB comprising the steps of:
selecting two adjacent through-hole vias on a printed circuit board (PCB),
wherein each via has a corresponding via pad, and
wherein the PCB has a ball grid array (BGA) of BGA pads on one side of the PCB arranged in a grid pattern;
covering each via with a respective solder mask;
removing areas from said solder masks,
wherein the areas overlap the holes of the respective through-hole vias;
placing solder pads in said areas; and
attaching a two-lead component to said two adjacent through-hole vias using said solder pads.

10. The method of claim 9, wherein the grid pattern is square.

11. The method of claim 10, wherein the grid pattern has 0.65 mm pitch.

12. The method of claim 9, wherein the grid pattern is substantially rectangular.

13. The method of claim 12, wherein the two adjacent through-hole vias are 0.65 mm apart, center to center.

14. The method of claim 9, wherein said solder pad is substantially rectangular.

15. The method of claim 9, wherein the two-lead component is an Imperial 0201 component.

16. The method of claim 15, wherein the Imperial 0201 component is a discrete component.

17. The method of claim 9, wherein the areas are substantially rectangular and each edge makes contact with the corresponding via pad.

18. A computer aided design tool implemented on a computing device for accommodating a two-lead component on in a 0.65 mm by 0.65 mm pitch ball grid array (BGA) printed circuit board (PCB) comprising:
a design tool mode configured to select two adjacent through-hole vias on the printed circuit board (PCB) for connection to a two-lead component
a design tool mode configured to identify a placement of solder pads and shape of solder pads on the two adjacent through-hole vias,
wherein the placement allows a two-lead component to connect to two adjacent through-hole vias, and
wherein the solder pads overlap the holes of the respective through-hole vias.
